(19) United States
(12) Patent Application Publication
(10) Pub. No.: US 2010/0056410 A1
(43) Pub. Date: Mar. 4, 2010

(54) COMPOSITIONS AND METHODS FOR THE REMOVAL OF PHOTORESIST FOR A WAFER REWORK APPLICATION

(75) Inventors: Pamela M. Visintin, North Charleston, SC (US); Michael B. Korzenski, Danbury, CT (US)

Correspondence Address: MOORE & VAN ALLEN PLLC, P.O. BOX 13706, Research Triangle Park, NC, 27709, US

(73) Assignee: ADVANCED TECHNOLOGY MATERIALS, INC., Danbury, CT (US)

(21) Appl. No.: 12/442,822

(22) PCT Filed: Sep. 25, 2007
(86) PCT No.: PCT/US07/79347

§ 371 Date: Oct. 23, 2009

Related U.S. Application Data
(60) Provisional application No. 60/826,840, filed on Sep. 25, 2006.
(60) Provisional application No. 60/943,714, filed on Jun. 13, 2007.

(51) Int. Cl. G03F 7/42

(52) U.S. Cl. 510/176

(57) ABSTRACT

Compositions useful in reworking microelectronic device wafers, i.e., removing photoresist from rejected wafers, without damaging underlying layers and structures such as cap layers, interlevel dielectric layers, etch stop layers and metal interconnect material. The semi-aqueous compositions include at least one alkali and/or alkaline earth metal basic salt, at least one organic solvent, water, optionally at least one quaternary ammonium basic salt, optionally at least one metal corrosion inhibitor and optionally at least one water-soluble polymer surfactant.

### FIELD OF THE INVENTION

The present invention relates to compositions and methods for off-site or in-house reworking of microelectronic device substrates.

### DESCRIPTION OF THE RELATED ART

When performing a photolithography process for manufacturing microelectronic devices having a stack structure, the overlay between a preformed lower layer and an upper layer must be checked. In addition, photoresist may be non-uniform, an incorrect photoresist film thickness may be observed, a poor quality photoresist film may be observed, and/or an incorrect feature dimension may occur. As microelectronic devices become highly integrated and reduced in size, the accuracy of the overlay between the lower layers and the upper layers, as well as the minimization of the other aforementioned processing failures, becomes increasingly more important to improve the reliability and yield of the microelectronic devices.

The quality of the photolithographic exposure step can be represented by a group of quality parameters such as the critical dimension, the overlay accuracy from layer to layer, the layer thickness, the absolute position accuracy (registration), etc. The extent to which the requirements must be fulfilled typically depends on the layer that is actually being structured. For example, some layers are structured with dense patterns, such that narrow tolerance ranges for the critical dimension exist. In other cases, two subsequent layers, one being structured above the other, require a minute adjustment to each other to provide contacts having a minimum cross-section in order to guarantee an accurate working function of the microelectronic device.

A set of tolerance specifications for the quality parameters are commonly deduced from the design rules and the layer architecture combined with current technology feasibilities. The specifications are generally provided prior to starting mass production of the wafers in a fabrication facility. That is, each of the metrology tools that measures at least one of the quality parameters is connected to a product database containing the pattern design files. The quality check, i.e., comparing whether the measured quality parameter is within the prescribed tolerance range for that parameter, is performed either on the metrology tool after having received the tolerance specification information, or after transferring its measured values to the MES-system (manufacturing execution system), which performs electronic data collection.

For example, once photoresist has been developed, scanning electron microscopy or other metrology techniques may be used to measure how closely the photoresist mask corresponds to its intended configuration. A go/no-go parameter may be established, and semiconductor wafers having photoresist patterns that are outside of the acceptance limits are removed from the production line for subsequent rework, i.e., the photoresist has to be stripped off. Wafers having acceptable photoresist masks are then processed through a further manufacturing step, such as for example, an etching process.

Unfortunately, the amount of rework is growing with the advent of tighter tolerance specifications introduced with advanced technologies. This disadvantageously increases the costs in material and tool time and also results in a loss in yield. Chemical removal of the photoresist material is a viable, time-effective and cost-effective method to rework the wafer rather than dispose of the wafer.

Towards that end, it is an object of the present invention to provide an improved composition and process whereby photoresist may be removed from rejected microelectronic device structures for off-site or in-house reworking of said structures, whereby the compositions and processes are compatible with existing manufacturing processes and components. Importantly, the compositions substantially remove photoresist without removing underlying layers such as, but not limited to, cap layers, interlevel dielectric layers, etch stop layers and metal interconnect material.

### SUMMARY OF THE INVENTION

The present invention relates to compositions for reworking of microelectronic device substrates, including compositions useful for the removal of photoresist from microelectronic device wafers having said photoresist thereon.

In one aspect, the present invention relates to a semi-aqueous composition comprising at least one alkali and/or alkaline earth metal basic salt, at least one organic solvent, water, optionally at least one quaternary ammonium basic salt, optionally at least one metal corrosion inhibitor, and optionally at least one water-soluble polymer surfactant, wherein said semi-aqueous composition is suitable for removing material selected from the group consisting of photoresist, anti-reflective coating (ARC), polymer-containing buildup, and combinations thereof, from a microelectronic device wafer having said material thereon. Importantly, said compositions are formulated such that the etch rate of silicon or silicon-containing material in the presence of said semi-aqueous compositions are less than 500 nm min⁻¹, preferably less than 300 nm min⁻¹, and most preferably less than 100 nm min⁻¹.

In another aspect, the present invention relates to a semi-aqueous composition comprising at least one alkali and/or alkaline earth metal basic salt, at least one quaternary ammonium basic salt, at least one organic solvent, water, optionally at least one metal corrosion inhibitor, and optionally at least one water-soluble polymer surfactant, wherein said semi-aqueous composition is suitable for removing material selected from the group consisting of photoresist, anti-reflective coating (ARC), polymer-containing buildup, and combinations thereof, from a microelectronic device wafer having said material thereon. Importantly, said compositions are formulated such that the etch rate of silicon or silicon-containing material in the presence of said semi-aqueous compositions are less than 500 nm min⁻¹, preferably less than 300 nm min⁻¹, and most preferably less than 100 nm min⁻¹

In yet another aspect, the present invention relates to a kit comprising, in one or more containers, one or more of the following reagents for forming an semi-aqueous composition, said one or more reagents selected from the group consisting of at least one alkali and/or alkaline earth metal basic salt, at least one organic solvent, water, optionally at least one quaternary ammonium basic salt, optionally at least one metal corrosion inhibitor, and optionally at least one water-soluble polymer surfactant, and wherein the kit is adapted to form a semi-aqueous composition suitable for removing material selected from the group consisting of photoresist, anti-reflective coating (ARC), polymer-containing buildup, and combinations thereof, from a microelectronic device wafer having said material thereon.

In still another aspect, the present invention relates to a method of reworking a microelectronic device wafer, said method comprising contacting the microelectronic device wafer with an semi-aqueous composition for sufficient time and under sufficient conditions to at least partially remove material selected from the group consisting of photoresist, anti-reflective coating (ARC), polymer-containing buildup, and combinations thereof, from the microelectronic device wafer having same thereon, wherein the semi-aqueous composition includes at least one alkali and/or alkaline earth metal basic salt, at least one organic solvent, water, optionally at least one quaternary ammonium basic salt, optionally at least one metal corrosion inhibitor, and optionally at least one water-soluble polymer surfactant.

Another aspect of the invention relates to a semi-aqueous composition comprising, consisting of, or consisting essentially of, cesium hydroxide, tetramethylammonium hydroxide, propylene glycol, water, optionally at least one metal corrosion inhibitor, and optionally at least one water-soluble polymer surfactant, wherein said semi-aqueous composition is suitable for removing material selected from the group consisting of photoresist, anti-reflective coating (ARC), polymer-containing buildup, and combinations thereof, from a microelectronic device wafer having said material thereon. Importantly, said compositions are formulated such that the etch rate of silicon or silicon-containing material in the presence of said semi-aqueous compositions are less than 500 nm min⁻¹, preferably less than 300 nm min⁻¹, and most preferably less than 100 nm min⁻¹

Another aspect of the invention relates to a method of manufacturing a microelectronic device, said method comprising contacting the microelectronic device with a semi-aqueous composition described herein for sufficient time to at least partially remove photoresist, ARC and/or polymer-containing buildup from the microelectronic device having said material thereon.

Yet another aspect of the invention relates to improved microelectronic devices, and products incorporating same, made using the methods of the invention comprising reworking a semiconductor device wafer using the methods and/or compositions described herein, and optionally, incorporating the microelectronic device into a product.

Another aspect of the invention relates to a semi-aqueous composition comprising at least one alkali and/or alkaline earth metal basic salt, at least one organic solvent, water, optionally at least one quaternary ammonium basic salt, optionally at least one metal corrosion inhibitor, optionally at least one water-soluble polymer surfactant, and residue material selected from the group consisting of photoresist, anti-reflective coating (ARC), polymer-containing buildup, and combinations thereof, wherein said semi-aqueous composition is suitable for removing material selected from the group consisting of photoresist, anti-reflective coating (ARC), polymer-containing buildup, and combinations thereof, from a microelectronic device wafer having said material thereon.

Another aspect of the invention relates to an article of manufacture comprising a semi-aqueous removal composition, a microelectronic device, and photoresist, ARC materials and/or polymer-containing buildup thereon, wherein the semi-aqueous removal composition comprises at least one alkali and/or alkaline earth metal basic salt, at least one organic solvent, water, optionally at least one quaternary ammonium basic salt, optionally at least one metal corrosion inhibitor, and optionally at least one water-soluble polymer surfactant.

Still another aspect of the invention relates to a method of reworking a microelectronic device structure to remove polymer-containing buildup from the backside and/or bevel edge of said structure, said method comprising:

protecting the front side of the structure from contact with a semi-aqueous composition; contacting the backside and/or bevel edge of the structure with the semi-aqueous composition of the invention for sufficient time and under sufficient contacting conditions to substantially remove the polymer-containing buildup from the backside and/or bevel edge of the structure.

In yet another aspect, the invention relates to a method of cleaning semiconductor tool parts, said method comprising contacting said tool parts with a composition for sufficient time to at least partially clean said tool parts, wherein the composition includes at least one alkali and/or alkaline earth metal basic salt, at least one organic solvent, water, optionally at least one quaternary ammonium basic salt, optionally at least one metal corrosion inhibitor, and optionally at least one water-soluble polymer surfactant.

Other aspects, features and embodiments of the invention will be more fully apparent from the ensuing disclosure and appended claims.

### DETAILED DESCRIPTION OF THE INVENTION, AND PREFERRED EMBODIMENTS THEREOF

The present invention relates to semi-aqueous compositions for reworking of microelectronic device substrates, including semi-aqueous compositions useful for the removal of photoresist from microelectronic device wafers having said photoresist thereon.

For ease of reference, “microelectronic device” corresponds to semiconductor substrates, flat panel displays, solar cells and photovoltaics, and microelectromechanical systems (MEMS), manufactured for use in microelectronic, integrated circuit, and computer chip applications. It is to be understood that the term “microelectronic device” is not meant to be limiting in any way and includes any substrate that will eventually become a microelectronic device, microelectronic assembly, or integrated circuit. Preferably, the microelectronic device comprises a wafer. The microelectronic device can be patterned, blanketed, a control and/or a test device. A “rejected microelectronic device” structure is intended to capture all structures that can be reworked, cleaned, recycled and/or reused according to the methods of the invention.

As used herein, “about” is intended to correspond to +5% of the stated value.

As used herein, “suitability” for removing material selected from the group consisting of photoresist, anti-reflective coating (ARC), polymer-containing buildup, and combinations thereof from a microelectronic device having said material(s) thereon corresponds to at least partial removal of said material(s) from the microelectronic device. Preferably, at least 90% of the material(s) are removed from the microelectronic device using the compositions of the invention, more preferably, at least 95%, and most preferably, at least 99% of the material(s) are removed.

As used herein, “reworking” the microelectronic device wafer corresponds to the substantial removal of the photoresist material, anti-reflective coating (ARC), polymer-containing buildup, and combinations thereof, subsequent to lithographic development and prior to subsequent etching processes. Alternatively, reworking includes the removal of polymer-containing buildup on the backside and/or bevel edge of the microelectronic device structure. Reworking may be performed off-site or in-house. Subsequent to reworking, the microelectronic device wafer may be recoated, baked, and re-patterned according to photolithographic techniques known in the art.

As defined herein, ARC layers correspond to bottom anti-reflective coating (BARC) layers and sacrificial anti-reflective coating (SARC) layers.

As defined herein, “cap layer” corresponds to materials that protect low-k dielectric materials from subsequent processes. Cap layers may lead to better topography control, process stability, and throughput. Cap layers include, but are not limited to, SiO₂ (e.g., TEOS, thermal oxide, sacrificial oxide), SiCOH, and Si₃N₄.

“Photoresist,” as used herein, refers to undeveloped, developed, hard baked, cross-linked, and/or thick film photoresist. By definition, thick film photoresist has a thickness in a range from about 5 μm to about 100 μm. It is to be understood that the term photoresist is not meant to be limiting in any way and includes any the materials that may be removed during wafer reworking including photoresist, ARC, polymer-containing buildup, and combinations thereof.

As used herein, the term “semi-aqueous” refers to a mixture of water and organic components. Semi-aqueous removal compositions must not substantially damage the layer to be retained located adjacent to the material to be removed using said composition. Depending on the desired results, the retained layers may include materials selected from the group consisting of may include the microelectronic device substrate, etch stop-layers, metal stack materials, barrier layer materials, ferroelectrics, silicides, nitrides, oxides, dielectrics (low-k and/or high-k), doped regions, and combinations thereof. “Not substantially damag[ing] the layer to be retained located adjacent to the material removed” means that less than 100 Å of retained layers are removed, more preferably less than 50 Å, even more preferably less than 20 Å, even more preferably less than 10 Å, and most preferred less than 1 Å of the retained layers are removed using the compositions of the invention. It is to be understood by one skilled in the art that a “layer” may be a blanket layer or a patterned layer.

As defined herein, “low-k dielectric material” corresponds to any material used as a dielectric material in a layered microelectronic device, wherein the material has a dielectric constant less than about 4. Preferably, the low-k dielectric materials include low-polarity materials such as silicon-containing organic polymers, silicon-containing hybrid organic/inorganic materials, organosilicate glass (OSG), TEOS, fluorinated silicate glass (FSG), and carbon-doped oxide (CDO) glass. For purposes of this invention, low-k dielectric material further includes silicon nitride materials. It is to be appreciated that the low-k dielectric materials may have varying densities and varying porosities.

As defined herein, “metal stack materials” correspond to: tantalum, tantalum nitride, titanium nitride, titanium, nickel, cobalt, tungsten, and silicides thereof, copper-containing layers; aluminum-containing layers; Al/Cu layers; alloys of Al; alloys of Cu; cobalt-containing layers such as CoWP and CoWBP; gold-containing layers; Au/Pt layers; hafnium oxides; hafnium oxysilicates; zirconium oxides; lanthanide oxides; titanates; nitrogen-doped analogues thereof, and combinations thereof on the microelectronic device.

As defined herein, “high-k dielectric” materials correspond to: hafnium oxides (e.g., HfO₂); zirconium oxides (e.g., ZrO₂); hafnium oxysilicates; hafnium silicates; zirconium silicates; titanium silicates; aluminum oxides; lanthanum-doped analogous thereof (e.g., LaAlO₃); aluminum silicates; titanates (e.g., Ta₂O₅); oxides and nitrides of hafnium and silicon (e.g., HfSiON); lanthanum-doped analogues thereof (e.g., HFSiON (La)); barium strontium titanate (BST); oxides of hafnium and aluminum (e.g., HfₓAl_{y}O_{z}); strontium titanate (SrTiO₃); barium titatnate (BaTiO₃); and combinations thereof.

As defined herein, “barrier layer material” corresponds to any material used in the art to seal the metal lines, e.g., copper interconnects, to minimize the diffusion of said metal, e.g. copper, into the dielectric material. Preferred barrier layer materials include silicon-rich nitrides, silicon-rich oxynitrides, tantalum, titanium, ruthenium, hafnium, tungsten, and other refractory metals and their nitrides and silicides.

As defined herein, “ferroelectrics” include, but are not limited to: barium titanate (BaTiO₃); lead titanate (PbTiO₃); lead zirconate titanate (PZT); lead lanthanum zirconate titanate (PLZT); lead magnesium niobate (PMN); Potassium Niobate (KNbO₃); Potassium Sodium Niobate (K×Na₁₋ₓNbO₃); Potassium Tantalate Niobate (K(TaₓNb₁₋ₓ)O₃); Lead niobate (PbNb₂O₆); bismuth titanate (Bi₄Ti₃O₁₂); lead bismuth niobate (PbBi₂Nb₂O₉); lithium niobate (LiNbO₃); lithium tantalate (LiTaO₃); strontium bismuth tantalate; strontium bismuth tantalate niobate; strontium tantalite; strontium titanate; and combinations and salts thereof.

As defined herein, “etch stop layers” include silicon carbide (SiC), silicon carbon nitride (SiCN), silicon carbon oxide (SiCO), silicon oxynitride (SiON), copper, silicon germanium (SiGe), SiGeB, SiGeC, AlAs, InGaP, InP, InGaAs, and combinations thereof.

As defined herein, “polymer-containing buildup” corresponds to the material that builds up on the backside and the bevel edge of the microelectronic device substrate during manufacturing and includes any of the materials deposited on the microelectronic device to that point including, but not limited to, low-k dielectric, a high-k dielectric, etch stop material, metal stack material, barrier layer material, ferroelectrics, silicides, nitrides, oxides, photoresist, bottom anti-reflective coating (BARC), sacrificial anti-reflective coating (SARC), miscellaneous materials, dopants, residue materials, chemical contaminants from other wet chemistries, and combinations thereof.

As defined herein, a “basic salt” corresponds to a hydroxide, a carbonate, a bicarbonate, a chloride, a bromide, an iodide, a nitrate, a nitrite, an oxide, a sulfide, a sulfite, a sulfate, an acetate and combinations thereof.

The requirements of a successful wafer rework include, but are not limited to, the substantial removal of photoresist, ARC and/or polymeric-containing buildup from the outermost edge and backside of the device substrate without substantial damage to the layer(s) to be retained, which reduces particle and metal contamination during subsequent processing.

Compositions of the invention may be embodied in a wide variety of specific formulations, as hereinafter more fully described.

In all such compositions, wherein specific components of the composition are discussed in reference to weight percentage ranges including a zero lower limit, it will be understood that such components may be present or absent in various specific embodiments of the composition, and that in instances where such components are present, they may be present at concentrations as low as 0.001 weight percent, based on the total weight of the composition in which such components are employed.

The semi-aqueous compositions of the invention are compositions including (i) at least one basic salt, (ii) at least one organic solvent, and (iii) water, which are present in the composition in relative amounts imparting to the composition an effectiveness for removing photoresist, ARC and/or polymeric-containing buildup from the microelectronic device wafer having same thereon. In another embodiment, the semi-aqueous compositions of the invention include (i) at least two basic salts, (ii) at least one organic solvent, and (iii) water. In still another embodiment, the semi-aqueous compositions of the invention include (i) at least one alkali and/or alkaline earth metal basic salt, (ii) at least one quaternary ammonium basic salt, (iii) at least one organic solvent, and (iv) water. In yet another embodiment, the semi-aqueous compositions of the invention include (i) cesium hydroxide, (ii) at least one quaternary ammonium basic salt, (iii) at least one organic solvent, and (iv) water. In yet another embodiment, the semi-aqueous compositions of the invention include (i) at least one quaternary ammonium basic salt, (ii) at least one alkali and/or alkaline earth metal basic salt (iii) at least one organic solvent, and (iv) water. In each embodiment, the semi-aqueous compositions of the invention may further include at least one metal corrosion inhibitor and/or at least one water-soluble polymer surfactant.

In the broad practice of the invention, the semi-aqueous compositions of the invention may comprise, consist of, or consist essentially of: (i) at least one basic salt, at least one organic solvent, and water, (ii) at least two basic salts, at least one organic solvent, and water, (iii) at least one alkali and/or alkaline earth metal basic salt, at least one quaternary ammonium basic salt, at least one organic solvent, and water, (iv) cesium hydroxide, at least one quaternary ammonium basic salt, at least one organic solvent, and water; or (v) at least one quaternary ammonium basic salt, at least one alkali and/or alkaline earth metal basic salt, at least one organic solvent, and water. In each embodiment, the semi-aqueous compositions of the invention may further comprise, consist of, or consist essentially of, at least one metal corrosion inhibitor and/or at least one water-soluble polymer surfactant. In general, the specific proportions and amounts of components, in relation to each other, may be suitably varied to provide the desired removal action of the composition for the photoresist, ARC materials, polymer-containing buildup and/or processing equipment, as readily determinable within the skill of the art without undue effort. The water is preferably deionized.

More specifically, the present invention relates to a semi-aqueous composition for removing photoresist, ARC and/or polymeric-containing buildup from the surface of a microelectronic device having same thereon, said composition including at least one alkali and/or alkaline earth metal basic salt, at least one organic solvent, water, optionally at least one quaternary ammonium basic salt, optionally at least one metal corrosion inhibitor, and optionally at least one water-soluble polymer surfactant, present in the following ranges, based on the total weight of the composition.

| | | preferred |
|---|---|---|
| component | % by weight | % by weight |
| alkali and/or alkaline | about 0.1 to about | about 0.2 to about |
| earth metal basic salt(s) | 10% | 1.5% |
| quaternary ammonium | 0 to about 5% | about 1% to about 5% |
| basic salt(s) | | |
| organic solvent(s) | about 20 to about 80% | about 25 to about 75% |
| water | about 10 to about 80% | about 20 to about 75% |
| metal corrosion inhibitor | 0 to about 20% | 0 to about 20% |
| water-soluble polymer | 0 to about 5% | 0 to about 5% |
| surfactant | | |

When present, the lower limit of quaternary ammonium basic salt(s), metal corrosion inhibitor(s) and water-soluble polymer surfactant(s) is about 0.01 wt. percent, based on the total weight of the composition.

The range of weight percent ratios of the components of the semi-aqueous composition is: about 20 to about 200 organic solvent(s) relative to alkali and/or alkaline earth metal basic salt(s), more preferably about 30 to about 100 or about 160 to about 180; and, when present, about 0.1 to about 10 quaternary ammonium basic salt(s) relative to alkali and/or alkaline earth metal basic salt(s), preferably about 2.5 to about 7. In a particularly preferred embodiment, the range of weight percent ratios of the components of the semi-aqueous composition includes about 160 to about 180 organic solvent(s) relative to alkali and/or alkaline earth metal basic salt(s) and about 5.5 to about 7 quaternary ammonium basic salt(s) relative to alkali and/or alkaline earth metal basic salt(s). In another particularly preferred embodiment, the range of weight percent ratios of the components of the semi-aqueous composition includes about 80 to about 100 organic solvent(s) relative to alkali and/or alkaline earth metal basic salt(s) and about 1.5 to about 3.5 quaternary ammonium basic salt(s) relative to alkali and/or alkaline earth metal basic salt(s).

Importantly, the semi-aqueous compositions of the invention are preferably substantially devoid of polishing pads and/or abrasives, hydrazine, and fluoride ions. “Substantially devoid” is defined herein as less than 2 wt. %, preferably less than 1 wt. %, more preferably less than 0.5 wt. %, and most preferably less than 0.1 wt. %.

Moreover, the inventors of the present invention have unexpectedly discovered that semi-aqueous compositions described herein, specifically the ratio of one component relative to another, does not substantially etch silicon or silicon-containing materials underlying the photoresist, ARC and/or polymer-containing buildup removed using said semi-aqueous composition. More specifically, the silicon or silicon-containing material etch rates in the presence of the semi-aqueous compositions of the invention are less than 500 nm min⁻¹, preferably less than 300 nm min⁻¹, and most preferably less than 100 nm min⁻¹.

It will be appreciated that in general reworking applications, it is common practice to make highly concentrated forms to be used at extreme dilutions. For example, the semi-aqueous composition may be diluted at the manufacturer, before use, and/or during use at the fab. Dilution ratios may be in a range from 1 part diluent: 10 part semi-aqueous composition to 10 parts diluent:1 part semi-aqueous composition. The preferred diluent includes deionized water and/or organic solvent. It is understood that upon dilution, the weight percent ratios of the components of the semi-aqueous composition will remain unchanged.

The pH of the semi-aqueous compositions may be varied to produce a composition optimized for the intended end use. In general, the pH will be basic, e.g., greater than about 10 and less than about 14, more preferably about 12 to about 14.

Illustrative organic solvents that may be useful in the semi-aqueous compositions of the invention include alcohols, amines, ethers, pyrrolidinones, glycols, and glycol ethers such as methanol, ethanol, isopropanol, and higher alcohols (including diols, triols, etc.), tetrahydrofuran (THF), N-methylpyrrolidinone (NMP), cyclohexylpyrrolidinone, N-octylpyrrolidinone, N-phenylpyrrolidinone, methyl formate, dimethyl formamide (DMF), dimethylsulfoxide (DMSO), 3-chloro-1,2-propanediol, tetramethylene sulfone (sulfolane), diethyl ether, phenoxy-2-propanol (PPh), propriopheneone, ethyl lactate, ethyl acetate, ethyl benzoate, acetonitrile, acetone, ethylene glycol, propylene glycol, dioxane, butyryl lactone, butylene carbonate, ethylene carbonate, propylene carbonate, dipropylene glycol, diethylene glycol monomethyl ether, triethylene glycol monomethyl ether, diethylene glycol monoethyl ether, triethylene glycol monoethyl ether, ethylene glycol monopropyl ether, ethylene glycol monobutyl ether, diethylene glycol monobutyl ether (i.e., butyl carbitol), triethylene glycol monobutyl ether, ethylene glycol monohexyl ether, diethylene glycol monohexyl ether, ethylene glycol phenyl ether, propylene glycol methyl ether, dipropylene glycol methyl ether, tripropylene glycol methyl ether, dipropylene glycol dimethyl ether, dipropylene glycol ethyl ether, propylene glycol n-propyl ether, dipropylene glycol n-propyl ether (DPGPE), tripropylene glycol n-propyl ether, propylene glycol n-butyl ether, dipropylene glycol n-butyl ether, tripropylene glycol n-butyl ether, propylene glycol phenyl ether, monoethanolamine, diethanolamine, triethanolamine, tertiarybutyldiethanolamine, isopropanolamine, diisopropanolamine (2-amino-1-propanol, 1-amino-2-propanol), triisopropanolamine, 3-amino-1-propanol, isobutanolamine, 2-(2-aminoethoxy)ethanol (diglycolamine), 2-amino-2-ethoxy-propanol, methylethanol amine, N,N-diethyl hydroxylamine, and combinations thereof. Preferably, the organic solvent comprises ethylene glycol, propylene glycol, or mixtures thereof.

Basic salt species contemplated herein include hydroxides, carbonates, bicarbonates, chlorides, bromides, iodides, nitrates, nitrites, oxides, sulfides, sulfites, sulfates, and/or acetates of cations having the formula: quaternary ammonium cations such as [NR¹R²R³R⁴]⁺, wherein R¹, R², R³ and R⁴ may be the same as or different from one another and are selected from the group consisting of hydrogen, straight-chained or branched C₁-C₆ alkyl (e.g., methyl, ethyl, propyl, butyl, pentyl, and hexyl), and substituted or unsubstituted C₆-C₁₀ aryl, e.g., benzyl, including tetramethylammonium hydroxide (TMAH), tetrabutylammonium hydroxide, tetraethylammonium hydroxide, benzyltriethylammonium hydroxide, benzyltrimethylammonium hydroxide, tributylmethylammonium hydroxide, and ammonium hydroxide; alkali metals including cesium, rubidium, potassium and sodium, e.g., cesium hydroxide, rubidium hydroxide, potassium hydroxide, sodium hydroxide; alkaline earth metals including calcium and magnesium, e.g., calcium hydroxide and magnesium hydroxide; and combinations thereof. Preferably, at least one alkali and/or alkaline earth metal basic salt is present, more preferably at least one alkali metal hydroxide and at least one quaternary ammonium hydroxide, and most preferably cesium hydroxide and at least one quaternary ammonium hydroxide. The preferred hydroxides include cesium hydroxide, TMAH, and combinations thereof.

The metal corrosion inhibitors serve to eliminate over-etching of metals, e.g., copper, cobalt, and/or tungsten interconnect metals. Suitable corrosion inhibitors include, but are not limited to: azoles such as benzotriazole (BTA), 1,2,4-triazole (TAZ), 5-aminotetrazole (ATA), 1-hydroxybenzotriazole, 5-amino-1,3,4-thiadiazol-2-thiol, 3-amino-1H-1,2,4 triazole, 3,5-diamino-1,2,4-triazole, tolyltriazole, 5-phenyl-benzotriazole, 5-nitro-benzotriazole, 3-amino-5-mercapto-1,2,4-triazole, 1-amino-1,2,4-triazole, 2-(5-amino-pentyl)-benzotriazole, 1-amino-1,2,3-triazole, 1-amino-5-methyl-1,2,3-triazole, 3-mercapto-1,2,4-triazole, 3-isopropyl-1,2,4-triazole, 5-phenylthiol-benzotriazole, halo-benzotriazoles (halo=F, Cl, Br or I), naphthotriazole, 1H-tetrazole-5-acetic acid, 2-mercaptobenzothiazole (2-MBT), 1-phenyl-2-tetrazoline-5-thione, 2-mercaptobenzimidazole (2-MBI), 4-methyl-2-phenylimidazole, 2-mercaptothiazoline, 2,4-diamino-6-methyl-1,3,5-triazine, thiazole, imidazole, benzimidazole, triazine, methyltetrazole, Bismuthiol I, 1,3-dimethyl-2-imidazolidinone, 1,5-pentamethylenetetrazole, 1-phenyl-5-mercaptotetrazole, diaminomethyltriazine, imidazoline thione, 4-methyl-4H-1,2,4-triazole-3-thiol, 5-amino-1,3,4-thiadiazole-2-thiol, benzothiazole, tritolyl phosphate, indiazole; DNA bases (e.g., glycine, adenine, cytosine, guanine, thymine); phosphate inhibitors; amines; pyrazoles; iminodiacetic acid (IDA); propanethiol; silanes; secondary amines; benzohydroxamic acids; heterocyclic nitrogen inhibitors; citric acid; ascorbic acid; L-cysteine, histidine; furanone; galactal; thiourea; 1,1,3,3-tetramethylurea; urea; urea derivatives; uric acid; potassium ethylxanthate; pyrazine; pyridazine; 2,3,5-trimethylpyrazine; 2-ethyl-3,5(6)-dimethylpyrazine; quinoxaline; benzimidazole; dicarboxylic acids such as oxalic acid, malonic acid, succinic acid, nitrilotriacetic acid, and acetylene dicarboxylic acid; and mixtures thereof. It is generally accepted that azoles chemisorb onto the copper surface and form an insoluble cuprous surface complex.

The surfactants may include water soluble polymers including, but not limited to, polyethylene glycol (PEG), polyethylene oxide (PEO), polyvinyl pyrrolidone (PVP), cationic polymers, nonionic polymers, anionic polymers, hydroxyethylcellulose (HEC), acrylamide polymers, poly(acrylic acid), carboxymethylcellulose (CMC), sodium carboxymethylcellulose (Na CMC), hydroxypropylmethylcellulose, polyvinylpyrrolidone K30, BIOCARE™ polymers, DOW™ latex powders (DLP), ETHOCEL™ ethylcellulose polymers, KYTAMER™ PC polymers, METHOCEL™ cellulose ethers, POLYOX™ water soluble resins, SoftCAT™ polymers, UCARE™ polymers, UCON™ fluids, and combinations thereof. The water soluble polymers may be short-chained or long-chained polymers and may be combined with the nonionic, anionic, cationic, and/or zwitterionic surfactants of the invention. When surfactants are included in the compositions of the invention, preferably defoaming agents are added in a range from 0 to 5 wt. %, based on the total weight of the composition. Defoaming agents contemplated include, but are not limited to, fatty acids, alcohols (simple or polyol) and amines such as caprylic acid diglyceride, lecithin, magnesium carbonate, polyethylene homopolymers and oxidised homopolymer M3400, dimethopolysiloxane-based, silicone-based, AGITAN™, and fatty acid polyether types such as LUMITEN™, oils, and combinations thereof.

In various preferred embodiments, the semi-aqueous compositions of the invention are formulated in the following Formulations A-J, wherein all percentages are by weight, based on the total weight of the formulation:

Formulation A: 2.00 wt. % TMAH; 0.75 wt. % CsOH; 70.50 wt. % ethylene glycol; 26.75 wt. % water
Formulation B: 2.00 wt. % TMAH; 0.75 wt. % CsOH; 70.50 wt. % propylene glycol; 26.75 wt. % water
Formulation C: 2.375 wt. % TMAH; 0.750 wt. % CsOH; 64.000 wt. % propylene glycol; 32.875 wt. % water
Formulation D: 2.375 wt. % TMAH; 0.375 wt. % CsOH; 64.000 wt. % propylene glycol; 33.250 wt. % water
Formulation E: 3.52 wt. % TMAH; 0.75 wt. % CsOH; 42.21 wt. % ethylene glycol; 53.52 wt. % water
Formulation F: 3.85 wt. % TMAH; 0.75 wt. % CsOH; 73.88 wt. % ethylene glycol; 21.52 wt. % water
Formulation G: 4.5 wt. % TMAH; 0.75 wt. % CsOH; 25.00 wt. % propylene glycol; 69.75 wt. % water
Formulation H: 2.38 wt. % TMAH; 0.75 wt. % CsOH; 25.00 wt. % propylene glycol; 71.87 wt. % water
Formulation I: 2.00 wt. % TMAH; 0.75 wt. % CsOH; 25.00 wt. % propylene glycol; 72.25 wt. % water
Formulation J: 2.38 wt. % TMAH; 0.75 wt. % CsOH; 44.50 wt. % propylene glycol; 52.37 wt. % water

Most preferably, the semi-aqueous compositions of the invention comprise, consist of, or consist essentially of, TMAH, CsOH, propylene glycol and water, wherein said compositions are formulated such that the silicon or silicon-containing material etch rates in the presence of said semi-aqueous compositions of the invention are less than 500 nm min⁻¹, preferably less than 300 nm min⁻¹, and most preferably less than 100 nm min⁻¹. In another preferred embodiment, the semi-aqueous compositions of the invention comprise, consist of, or consist essentially of, TMAH, CsOH, ethylene glycol and water, wherein said compositions are formulated such that the silicon or silicon-containing material etch rates in the presence of said semi-aqueous compositions of the invention are less than 500 nm min⁻¹, preferably less than 300 nm min⁻¹, and most preferably less than 100 nm min⁻¹.

Importantly, the semi-aqueous compositions of the invention remove photoresist, ARC, polymer-containing buildup and combinations thereof without deleteriously attacking the underlying stack materials such as cap layers, metal stack materials, barrier layer materials, ferroelectrics, silicides, nitrides, oxides, dielectrics (low-k and/or high-k), etch stop layers, metal interconnect materials, and combinations thereof. In addition, the semi-aqueous compositions readily remove post-etch and post-ash residue from a microelectronic device having same thereon.

In another aspect, the aforementioned semi-aqueous compositions of the invention further include residue material selected from the group consisting of photoresist, ARC, polymer-containing buildup, and combinations thereof. For example, the semi-aqueous composition may include at least one alkali and/or alkaline earth metal basic salt, at least one organic solvent, water, at least one quaternary ammonium basic salt, and residue material. In another embodiment, the semi-aqueous composition of the invention may include at least one alkali and/or alkaline earth metal basic salt, at least one quaternary ammonium basic salt, at least one organic solvent, water, and residue material. In each embodiment, the semi-aqueous composition may further include at least one metal corrosion inhibitor and/or at least one water-soluble polymer surfactant. For example, a particularly preferred composition of the invention may comprise, consist of, or consist essentially of TMAH, CsOH, propylene glycol, water, and residue material selected from the group consisting of photoresist, ARC, polymer-containing buildup, and combinations thereof, wherein said compositions are formulated such that the silicon or silicon-containing material etch rates in the presence of said semi-aqueous compositions of the invention are less than 500 nm min⁻¹, preferably less than 300 nm min⁻¹, and most preferably less than 100 nm min⁻¹. Importantly, the residue material may be dissolved and/or suspended in the removal composition of the invention.

The semi-aqueous compositions of the invention are easily formulated by simple addition of the respective ingredients and mixing to homogeneous condition. Furthermore, the semi-aqueous compositions may be readily formulated as single-package formulations or multi-part formulations that are mixed at or before the point of use, e.g., the individual parts of the multi-part formulation may be mixed at the tool or in a storage tank upstream of the tool. The concentrations of the respective ingredients may be widely varied in specific multiples of the semi-aqueous composition, i.e., more dilute or more concentrated, in the broad practice of the invention, and it will be appreciated that the removal compositions of the invention can variously and alternatively comprise, consist or consist essentially of any combination of ingredients consistent with the disclosure herein. In one embodiment, the concentrates of the semi-aqueous composition are anhydrous and water is to be added to said concentrates by the user at the fab to produce the semi-aqueous composition of the invention.

Accordingly, another aspect of the invention relates to a kit including, in one or more containers, one or more components adapted to form the compositions of the invention. For example, the kit may include, in one or more containers, at least one alkali and/or alkaline earth metal basic salt, at least one organic solvent, optionally water, optionally at least one quaternary ammonium basic salt, optionally at least one metal corrosion inhibitor, and optionally at least one water-soluble polymer surfactant, for combining with each other or alternatively with additional water and/or organic solvent at the fab or the point of use. In another embodiment, the kit may include, in one or more containers, at least one alkali and/or alkaline earth metal basic salt, at least one organic solvent, at least one quaternary ammonium basic salt, optionally water, optionally at least one metal corrosion inhibitor, and optionally at least one water-soluble polymer surfactant, for combining with each other or alternatively with additional water and/or organic solvent at the fab or the point of use. In yet another embodiment, the kit may include, in one or more containers, at least one alkali metal basic salt, at least one quaternary ammonium basic salt, at least one organic solvent, optionally water, optionally at least one metal corrosion inhibitor, and optionally at least one water-soluble polymer surfactant, for combining with each other or alternatively with additional water and/or organic solvent at the fab or the point of use. The containers of the kit must be suitable for storing and shipping said semi-aqueous compositions, for example, NOWPak® containers (Advanced Technology Materials, Inc., Danbury, Conn., USA).

The one or more containers which contain the components of the semi-aqueous composition preferably include means for bringing the components in said one or more containers in fluid communication for blending and dispense. For example, referring to the NOWPak® containers, gas pressure may be applied to the outside of a liner in said one or more containers to cause at least a portion of the contents of the liner to be discharged and hence enable fluid communication for blending and dispense. Alternatively, gas pressure may be applied to the head space of a conventional pressurizable container or a pump may be used to enable fluid communication. In addition, the system preferably includes a dispensing port for dispensing the blended removal composition to a process tool.

Substantially chemically inert, impurity-free, flexible and resilient polymeric film materials, such as high density polyethylene, are preferably used to fabricate the liners for said one or more containers. Desirable liner materials are processed without requiring co-extrusion or barrier layers, and without any pigments, UV inhibitors, or processing agents that may adversely affect the purity requirements for components to be disposed in the liner. A listing of desirable liner materials include films comprising virgin (additive-free) polyethylene, virgin polytetrafluoroethylene (PTFE), polypropylene, polyurethane, polyvinylidene chloride, polyvinylchloride, polyacetal, polystyrene, polyacrylonitrile, polybutylene, and so on. Preferred thicknesses of such liner materials are in a range from about 5 mils (0.005 inch) to about 30 mils (0.030 inch), as for example a thickness of 20 mils (0.020 inch).

Regarding the containers for the kits of the invention, the disclosures of the following patents and patent applications are hereby incorporated herein by reference in their respective entireties: U.S. Pat. No. 7,188,644 entitled “APPARATUS AND METHOD FOR MINIMIZING THE GENERATION OF PARTICLES IN ULTRAPURE LIQUIDS;” U.S. Pat. No. 6,698,619 entitled “RETURNABLE AND REUSABLE, BAG-IN-DRUM FLUID STORAGE AND DISPENSING CONTAINER SYSTEM;” and U.S. Patent Application No. 60/916,966 entitled “SYSTEMS AND METHODS FOR MATERIAL BLENDING AND DISTRIBUTION” filed on May 9, 2007 in the name of John E.Q. Hughes.

Proposed kits include, in one container, at least one alkali and/or alkaline earth metal basic salt, at least one organic solvent, water, at least one quaternary ammonium basic salt (when present), at least one metal corrosion inhibitor (when present), and at least one water-soluble polymer surfactant (when present), for combining with additional water and/or additional solvent at the fab or the point of use. In the alternative, the kit may include two containers, one container including the at least one alkali and/or alkaline earth metal basic salt as a solid or as an aqueous solution, and the other container including at least one organic solvent, water, at least one quaternary ammonium basic salt (when present), at least one metal corrosion inhibitor (when present), and at least one water-soluble polymer surfactant (when present) for combining with additional water and/or additional solvent at the fab or the point of use. In each case, additional water and/or organic solvent may be added directly to the container system and/or at a subsequent blending/dilution vessel.

In photoresist, ARC and/or polymer-containing buildup removal application, i.e., microelectronic device wafer rework, the composition is applied in any suitable manner to the device wafer to be reworked, e.g., by spraying the composition on the surface of the device wafer to be reworked, by dipping (in a volume of the composition) the device wafer to be reworked, by contacting the device wafer to be reworked with another material, e.g., a pad, or fibrous sorbent applicator element, that is saturated with the composition, or by any other suitable means, manner or technique by which the composition is brought into removal contact with the device wafer to be reworked. Further, batch or single wafer processing is contemplated herein. Tool sets contemplated herein include, but are not limited to, wet bench and/or single wafer tools.

In use of the compositions of the invention for removing photoresist, ARC, and/or polymer-containing buildup from the microelectronic devices requiring reworking, the composition typically is contacted with the device wafer for a time of from about 1 minutes to about 60 minutes, preferably about 2 minutes to about 10 minutes, and most preferably about 5 minutes, at temperature in a range of from about 30° C. to about 80° C., preferably about 50° C. to about 70° C., most preferably about 60° C. Such contacting times and temperatures are illustrative, and any other suitable time and temperature conditions may be employed that are efficacious to at least partially remove photoresist, ARC, polymer-containing buildup, and combinations thereof, from the device wafer, within the broad practice of the invention. As defined herein, “at least partial removal” corresponds to at least 90% removal of the material, preferably at least 95% removal of the material and most preferably, at least 99% of the material is removed using the compositions of the present invention.

Following the achievement of the desired removal action, the semi-aqueous composition may be readily removed from the device to which it has previously been applied, as may be desired and efficacious in a given end use application of the compositions of the present invention. For example, the device may be rinsed with a rinse solution including deionized water and/or isopropyl alcohol and/or dried (e.g., spin-dry, N₂, vapor-dry etc.).

It should be appreciated that the semi-aqueous compositions of the invention may be used to remove photoresist in a non-reworking wet chemical removal application, e.g., the removal of photoresist and/or ARC materials from a non-rejected microelectronic device, subsequent to etching processes known in the art, wherein the photoresist may be highly hardened, i.e., highly cross-linked, bulk photoresist, or thick photoresist.

In a further aspect, the semi-aqueous compositions of the invention may be used to rework the microelectronic device structure, whereby the polymer-containing buildup on the backside and/or bevel edge of the structure is removed. Importantly, the process of removing the polymer-containing buildup from the backside and/or bevel edge of the structure may, but not necessarily, require protecting the front-side of the structure from exposure to the composition. Such a process may include the positioning of the structure in a single wafer tool that protects the front side of the wafer using an inert gas, e.g., nitrogen, and/or a deionized water spray. Alternatively, the front side may be protected by depositing a thick layer of photoresist or other protective coating polymer on the front side. In other words, if the front side of the structure includes patterned and/or blanketed material(s) that should not be exposed to the semi-aqueous compositions of the invention when cleaning the backside and/or bevel edge, the front side should be protected. In another embodiment, both the front side and the backside/bevel edge is exposed to the semi-aqueous compositions of the invention to simultaneously remove material from the front side (e.g., photoresist, etc.) and the backside/bevel edge (e.g., polymer-containing buildup and copper-containing material).

Microelectronic device wafers may be reworked off-site or in-house. In-house reworking and recycling has the advantage of increasing the overall yield, decreasing the overall costs and reducing the cycle time between the diagnostic process and the rework.

Yet another aspect of the invention relates to the improved microelectronic devices made according to the methods of the invention and to products containing such microelectronic devices. For example, a rejected microelectronic device wafer may be reworked using the compositions and/or methods of the invention and subsequently the microelectronic device wafer may be recoated, baked, and re-patterned according to photolithographic techniques known in the art, multiple times. The inventors have surprisingly and unexpectedly discovered that the same microelectronic device structure may be reworked, e.g., photoresist and ARC material(s) are removed from the microelectronic device structure, upwards of ten times. For example, the same structure may be photolithographically processed and subsequently reworked to remove the erroneously positioned photoresist pattern greater than or equal to two times, preferably greater than or equal to five times, and most preferably, greater than or equal to ten times, wherein said rework does not substantially damage the layer(s) to be retained. Importantly, unlike rework compositions in the prior art (e.g., physical polish of the edge, a dry plasma etch, combustion, etc.) the at least one material to be removed from the microelectronic device structure may be removed in a single step with a semi-aqueous composition of the invention.

In addition, the inventors surprisingly discovered that the backside and/or bevel edge of the microelectronic device structure may be readily cleaned, e.g., polymer-containing buildup, is removed from the backside and/or bevel edge of the microelectronic device structure.

In another aspect, the invention relates to a method of removing post-etch and/or post-ash residue from the microelectronic device wafer having same thereon using the semi-aqueous compositions of the invention. When the semi-aqueous removal compositions of the invention are used to remove post-etch and/or post-ash residue, the removal composition may further include post-etch and/or post-ash residue material.

In still another aspect, the present invention relates to an article comprising a reworked microelectronic device structure or reworked microelectronic device substrate and at least one additional material layer selected from the group consisting of low-k dielectric material, high-k dielectric materials, etch stop layers, metal stack materials, nitrides, silicides, oxides, ferroelectrics, barrier layer materials, photoresist, ARC material, doped regions, and combinations thereof, wherein the at least one additional material layer was deposited onto the microelectronic device structure or substrate subsequent to reworking. The article may further comprise an intermediate layer positioned between the microelectronic device structure or substrate and the at least one additional material layer.

A still further aspect of the invention relates to methods of manufacturing an article comprising a microelectronic device, said method comprising reworking the microelectronic device using a composition for sufficient time to remove photoresist, ARC, polymer-containing buildup, and combinations thereof, from the microelectronic device having said materials thereon, and eventually incorporating said microelectronic device into said article, wherein the composition includes at least one alkali and/or alkaline earth metal basic salt, at least one organic solvent, water, optionally at least one quaternary ammonium basic salt, optionally at least one metal corrosion inhibitor, and optionally at least one water-soluble polymer surfactant.

In addition, it is contemplated herein that the semi-aqueous compositions of the invention may be diluted with a solvent such as water and used as a post-chemical mechanical polishing (CMP) composition to remove post-CMP residue including, but not limited to, particles from the polishing slurry, carbon-rich particles, polishing pad particles, brush deloading particles, equipment materials of construction particles, copper, copper oxides, and any other materials that are the by-products of the CMP process. Preferred dilution ratios are about 10:1 to about 200:1 diluent to concentrate. When the semi-aqueous removal compositions of the invention are used to remove post-CMP residue, the removal composition may further include post-CMP residue material.

In still another aspect, the invention relates to a method of cleaning semiconductor tool parts, said method comprising contacting said tool parts with a composition for sufficient time to clean said parts, wherein the composition includes at least one alkali and/or alkaline earth metal basic salt, at least one organic solvent, water, optionally at least one quaternary ammonium basic salt, optionally at least one metal corrosion inhibitor, and optionally at least one water-soluble polymer surfactant. In cleaning application, the composition is applied in any suitable manner to the tool part to be cleaned, e.g., by spraying the composition on the surface of the tool part to be cleaned, by dipping (in a volume of the composition) the tool part to be cleaned, by contacting the tool part to be cleaned with another material, e.g., a pad, or fibrous sorbent applicator element, that is saturated with the composition, or by any other suitable means, manner or technique by which the composition is brought into removal contact with the tool part to be cleaned. Typically, tool parts include many of the same material that is to be removed from the microelectronic device, e.g., photoresist, ARC materials and/or polymer-containing buildup.

In another aspect, the present invention further relates to a process of to minimizing evaporation of the semi-aqueous composition over time by including a layer of material(s) on the bath to minimize evaporative effects. Notably, the layer has to include a material or materials that will not substantially dissolve or intermingle in the compositions of the bath. For example, TEFLON® coated materials or TEFLON® materials that float on the surface of the bath, i.e., are less dense than the bath, may be used to completely cover the bath and slow evaporation, thereby increasing the bath life. TEFLON® coated materials may include hollow, lightweight shapes such as spheres and other polygonal shapes. The shapes may be symmetrical or unsymmetrical. Alternatively, the TEFLON® coated materials may be a shape that is designed to easily fit over the bath, e.g., a floating lid.

Following processing, the compositions of the invention may be further processed to lower the chemical oxygen demand (COD) of the waste water stream in the fabrication facility. For example, mixed aqueous-organic formulations may be treated with (1) carbon, preferably a polyvinylidene chloride (PVDC) monolith carbon having micropores less than 1 nm wide, which will “scrub” the organic solvent from the composition, and/or (2) acids such as HCl, H₂SO₄, HNO₃, acetic acid, ascorbic acid, amino acids, and combinations thereof. The treatments may be sequential or in a one-step mixed bed approach. The waste water stream of the fab should be exposed to the treatment(s) until the COD is lowered to promulgated acceptable levels.

The following Examples are merely illustrative of the invention and are not intended to be limiting.

### Example 1

A wafer including photoresist, ARC, a TEOS cap layer, a SiCOH ILD, a silicon carbide etch stop layer, and copper interconnect material was statically immersed in Formulations A, and C—H for 5 minutes at 60° C., rinsed with water, rinsed with isopropyl alcohol, and dried with N₂. The wafers were subjected to field emission scanning electron microscopy (FESEM) to determine if the photoresist material and ARC material were removed from the wafer. The results are described in Table 1 below.

TABLE 1
Photoresist removal results for Formulations A and C-H.

| Formulation | Results |
|---|---|
| A | Substantial delamination of the photoresist from the |
| | surface; no observed residues |
| C | Substantial delamination of the photoresist from the |
| | surface; no observed residues |
| D | Substantial delamination of the photoresist from the |
| | surface; no observed residues |
| E | Substantial delamination of the photoresist from the |
| | surface; no observed residues |
| F | Substantial delamination of the photoresist from the |
| | surface; no observed residues |
| G | Substantial delamination of the photoresist from the |
| | surface; no observed residues |
| H | Substantial delamination of the photoresist from the |
| | surface; no observed residues |

As defined herein, “substantial delamination” corresponds to the removal of at least 95% of the photoresist and ARC materials, more preferably at least 98% and most preferably at least 99% of the photoresist and ARC materials are removed using the compositions of the invention. In the present case, 98-100% of the photoresist and ARC was removed using formulations A and C—H.

Importantly, when the wafer was statically immersed in compositions devoid of the at least one additional basic salt (Formulation K: 0.87 wt. % CsOH; 49.13 wt. % EG; 50 wt. % water and Formulation L: 3.55 wt. % TMAH; 42.90 wt. % EG; 53.55 wt. % water), it was determined that Formulation K did not substantially delaminate the photoresist and Formulation L did substantially delaminate the photoresist, however, deleterious amounts of large residue remained on the surface of the underlying cap layer materials.

### Example 2

Blanketed TEOS and Black Diamond™ (hereinafter BD) wafers were statically immersed in Formulations A-I at 60° C. for 5 minutes to determine the respective etch rates of the materials in the presence of the formulations. Etch rates were determined using a NanoSpec. The results are tabulated in Table 2 below.

TABLE 2
Etch rates of TEOS and BD in Formulations A-I.

| | Etch rate | Etch rate |
|---|---|---|
| Formulation | TEOS/Å min⁻¹ | BD/Å min⁻¹ |
| A | 0 | 0 |
| B | 0 | 0 |
| C | 0 | 0 |
| D | 0 | 0 |
| E | 0 | 0 |
| F | 0 | 0 |
| G | 2.2 | 0 |
| H | 1.6 | 0 |
| I | 2.0 | 0 |

It can be seen that Formulations A-I can be used to successfully removed the photoresist material while not attacking the adjacently underlying materials, i.e., TEOS and BD. In addition, it can be concluded that water significantly increases the TEOS etch rate, while propylene glycol significantly decreases the TEOS etch rate. The use of propylene glycol has the added advantage of being a non-hazardous air pollutant (non-HAP).

Surprisingly, analogous experiments performed using compositions formulated similarly to Formulation A and B, whereby the CsOH was substituted with KOH, revealed that the use of KOH instead of CsOH resulted in relatively high levels of TEOS and BD etching (60° C., 5 min), as summarized in Table 3 below.

| | Etch rate | Etch rate |
|---|---|---|
| Formulation | TEOS/Å min⁻¹ | BD/Å min⁻¹ |
| 2.00 wt. % TMAH; | 5.2 | 7.6 |
| 0.75 wt. % KOH; | | |
| 70.50 wt. % ethylene glycol; | | |
| 26.75 wt. % water | | |
| 2.00 wt. % TMAH; | 14 (visible etching) | 4.4 |
| 0.75 wt. % KOH; | | |
| 70.50 wt. % propylene glycol; | | |
| 26.75 wt. % water | | |

Although not wishing to be bound by theory, it is thought that the larger Cs⁺ cation substantially eliminates etching of the underlying material, i.e., TEOS and BD, relative to that of the much smaller K⁺ cation, which clearly has a deleterious effect on TEOS and BD.

While the invention has been described herein in reference to specific aspects, features and illustrative embodiments of the invention, it will be appreciated that the utility of the invention is not thus limited, but rather extends to and encompasses numerous other variations, modifications and alternative embodiments, as will suggest themselves to those of ordinary skill in the field of the present invention, based on the disclosure herein. Correspondingly, the invention as hereinafter claimed is intended to be broadly construed and interpreted, as including all such variations, modifications and alternative embodiments, within its spirit and scope.

1. A semi-aqueous composition comprising at least one alkali and/or alkaline earth metal basic salt, at least one organic solvent, water, optionally at least one quaternary ammonium basic salt, optionally at least one metal corrosion inhibitor, and optionally at least one water-soluble polymer surfactant.

2. (canceled)

3. The composition of claim 1, wherein the at least one alkali and/or alkaline earth metal basic salt comprises a hydroxide selected from the group consisting of cesium hydroxide, rubidium hydroxide, potassium hydroxide, sodium hydroxide, calcium hydroxide, magnesium hydroxide, and combinations thereof.

4. The composition of claim 1, wherein the at least one alkali and/or alkaline earth metal basic salt comprises cesium hydroxide.

5. The composition of claim 1, wherein the semi-aqueous composition comprises the at least one quaternary ammonium basic salt having the formula NR¹R²R³R⁴OH, wherein R¹, R², R³ and R⁴ may be the same as or different from one another and are selected from the group consisting of hydrogen straight-chained C₁-C₆ alkyl branched C₁-C₆ alkyl substituted C₆-C₁₀aryl and unsubstituted C₆-C₁₀aryl.

6. (canceled)

7. The composition of claim 5, wherein the at least one quaternary ammonium basic salt comprises a hydroxide selected from the group consisting of tetramethylammonium hydroxide, tetrabutylammonium hydroxide, tetraethylammonium hydroxide, benzyltriethylammonium hydroxide, benzyltrimethylammonium hydroxide, tributylmethylammonium hydroxide, ammonium hydroxide, and combinations thereof.

8. (canceled)

9. (canceled)

10. The composition of claim 1, wherein at least one organic solvent comprises a species selected from the group consisting of methanol, ethanol, isopropanol, and higher alcohols (including diols, triols, etc.), tetrahydrofuran (THF), N-methylpyrrolidinone (NMP), cyclohexylpyrrolidinone, N-octylpyrrolidinone, N-phenylpyrrolidinone, methyl formate, dimethyl formamide (DMF), dimethylsulfoxide (DMSO), tetramethylene sulfone (sulfolane), diethyl ether, phenoxy-2-propanol (PPh), 3-chloro-1,2,-propanediol, propriopheneone, ethyl lactate, ethyl acetate, ethyl benzoate, acetonitrile, acetone, ethylene glycol, propylene glycol, dioxane, butyryl lactone, butylene carbonate, ethylene carbonate, propylene carbonate, dipropylene glycol, diethylene glycol monomethyl ether, triethylene glycol monomethyl ether, diethylene glycol monoethyl ether, triethylene glycol monoethyl ether, ethylene glycol monopropyl ether, ethylene glycol monobutyl ether, diethylene glycol monobutyl ether (i.e., butyl carbitol), triethylene glycol monobutyl ether, ethylene glycol monohexyl ether, diethylene glycol monohexyl ether, ethylene glycol phenyl ether, propylene glycol methyl ether, dipropylene glycol methyl ether, tripropylene glycol methyl ether, dipropylene glycol dimethyl ether, dipropylene glycol ethyl ether, propylene glycol n-propyl ether, dipropylene glycol n-propyl ether (DPGPE), tripropylene glycol n-propyl ether, propylene glycol n-butyl ether, dipropylene glycol n-butyl ether, tripropylene glycol n-butyl ether, propylene glycol phenyl ether, and combinations thereof.

11. The composition of claim 1, wherein the at least one organic solvent comprises a species selected from the group consisting of propylene glycol, ethylene glycol and combinations thereof.

12. (canceled)

13. (canceled)

14. (canceled)

15. The composition of claim 1, wherein the pH of the composition is in a range from about 10 to about 14.

16. The composition of claim 1, wherein said semi-aqueous composition further comprises residue material selected from the group consisting of photoresist, anti-reflective coating (ARC), polymer-containing buildup, post-CMP residue and combinations thereof.

17. The composition of claim 1, wherein the composition includes TMAH, CsOH, propylene glycol and water.

18. The composition of claim 1, wherein said composition is substantially devoid of polishing pads and/or abrasives, hydrazine, and fluoride ions.

19. (canceled)

20. The composition of claim 1, comprising the at least one metal corrosion inhibitor.

21. A kit comprising, in one or more containers, one or more of the following reagents for forming an semi-aqueous composition, said one or more reagents selected from the group consisting of at least one alkali and/or alkaline earth metal basic salt, at least one organic solvent, water, optionally at least one quaternary ammonium basic salt, optionally at least one metal corrosion inhibitor, and optionally at least one water-soluble polymer surfactant, and wherein the kit is adapted to form a semi-aqueous composition suitable for removing material selected from the group consisting of photoresist, anti-reflective coating (ARC), polymer-containing buildup, post-CMP residue and combinations thereof, from a microelectronic device wafer having said material thereon.

22. (canceled)

23. A method of reworking a microelectronic device wafer, said method comprising contacting the microelectronic device wafer with an semi-aqueous composition for sufficient time and under sufficient conditions to at least partially remove material selected from the group consisting of photoresist, anti-reflective coating (ARC), polymer-containing buildup, post-CMP residue and combinations thereof, from the microelectronic device wafer having same thereon, wherein the semi-aqueous composition includes at least one alkali and/or alkaline earth metal basic salt, at least one organic solvent, water, optionally at least one quaternary ammonium basic salt, optionally at least one metal corrosion inhibitor, and optionally at least one water-soluble polymer surfactant.

24. The method of claim 23, wherein said contacting is carried out under conditions selected from the group consisting of: time in a range from about 1 minute to about 60 minutes; temperature in a range of from about 30° C. to about 80° C.; and combinations thereof.

25. The method of claim 23, wherein the at least one alkali and/or alkaline earth metal basic salt comprises a species selected from the group consisting of alkali metal hydroxides; alkaline earth metal hydroxides; and combinations thereof; and
wherein at least one organic solvent comprises a species selected from the group consisting of alcohols, diols, triols, pyrrolidinones, glycols, carbonates, glycol ethers, and combinations thereof.

26. The method of claim 23, wherein the semi-aqueous composition comprises the at least one quaternary ammonium basic salt having the formula NR¹R²R³R⁴OH, wherein R¹, R², R³ and R⁴ may be the same as or different from one another and are selected from the group consisting of hydrogen straight-chained C₁-C₆ alkyl branched C₁-C₆ alkyl substituted C₆-C₁₀aryl and unsubstituted C₆-C₁₀aryl.

27.-31. (canceled)

32. The method of claim 23, wherein the semi-aqueous composition further comprises material selected from the group consisting of photoresist, anti-reflective coating (ARC), polymer-containing buildup, post-CMP residue and combinations thereof.

33. The method of claim 23, wherein the contacting comprises a process selected from the group consisting of: spraying the semi-aqueous composition on a surface of the microelectronic device;
dipping the microelectronic device in a sufficient volume of semi-aqueous composition; contacting a surface of the microelectronic device with another material that is saturated with the semi-aqueous composition; and contacting the microelectronic device with a circulating semi-aqueous composition.

34. The method of claim 23, further comprising rinsing the microelectronic device with a rinsing composition following contact with the removal composition wherein the rinsing composition comprises deionized water.

35.-38. (canceled)
